(19) United States
(12) Patent Application Publication
(10) Pub. No.: US 2024/0234308 A9
(43) Pub. Date: Jul. 11, 2024

(54) SEMICONDUCTOR APPARATUS AND METHOD FOR MANUFACTURING SEMICONDUCTOR APPARATUS

(71) Applicants: ADVANTEST CORPORATION, Tokyo (JP); Tokyo Institute of Technology, Tokyo (JP)

(72) Inventors: Shinji SUGATANI, Saitama (JP); Takayuki OHBA, Kanagawa (JP); Koji SAKUI, Tokyo (JP); Norio CHUJO, Tokyo (JP)

(21) Appl. No.: 18/450,420

(22) Filed: Aug. 16, 2023

(30) Foreign Application Priority Data
Oct. 25, 2022 (JP) 2022-171012

(51) Int. Cl. H01L 23/528; H01L 21/8238; H01L 27/092; H01L 29/06; H01L 29/423; H01L 29/775

(52) U.S. Cl. CPC H01L 23/528; H01L 21/823871; H01L 27/092; H01L 29/0673; H01L 29/42392; H01L 29/775

(57) ABSTRACT

To provide a semiconductor apparatus including a transistor element layer having a plurality of transistors which are multi-gate transistors of a floating body structure, a first wiring layer having at least one signal line which electrically connects between a source and a gate or between a drain and a gate of at least one pair of transistors among the plurality of transistors, the first wiring layer being laminated on the side of one surface of the transistor element layer, and a second wiring layer having at least one signal line which electrically connects between a source and a gate or between a drain and a gate of at least another pair of transistors among the plurality of transistors, the second wiring layer being laminated on the side of another surface of the transistor element layer.

The contents of the following patent application(s) are incorporated herein by reference: NO. 2022-171012 filed in JP on Oct. 25, 2022

### TECHNICAL FIELD

The present invention relates to a semiconductor apparatus and a method for manufacturing the semiconductor apparatus.

### BACKGROUND

Patent document 1 describes, “the power supply wirings 11 to 13 are embedded power supply wirings (BPR: Buried Power Rail) formed in the embedded wiring layer, respectively” (paragraph 0048). Patent document 2 describes, “using an insulated gate type field effect transistor (TFT) formed on an insulating material such as glass or an insulating surface such as silicon oxide provided on a silicon wafer” (paragraph 0001). Patent document 3 describes, “CMOS comprises: lower semiconductor layers (11, 12) provided on a semiconductor substrate 1 . . . ; upper semiconductor layers (15-17) provided via laminated interlayer insulation films 6 . . . in which P channel and N channel MIS field effect transistors has a laminated structure” (Abstract).

### PRIOR ART DOCUMENT

### Patent Document

Patent Document 1: WO2021/166645
Patent Document 2: Japanese Patent Application Publication No. H07-193188
Patent Document 3: Japanese Patent Application Publication No. 2018-107231

### BRIEF DESCRIPTION OF THE DRAWINGS

FIG. 1 is a schematic perspective view of a semiconductor apparatus 10 according to a first embodiment.

FIG. 2 is a schematic perspective view in which the semiconductor apparatus 10 shown in FIG. 1 is disassembled in half along a Y-axis direction.

FIG. 3 is an example of a circuit diagram of the semiconductor apparatus 10 according to the first embodiment.

FIG. 4 is a diagram for describing a manufacturing method of the semiconductor apparatus 10 according to the first embodiment.

FIG. 5 is a diagram showing the state shown in FIG. 4 from the positive direction side of an X-axis.

FIG. 6 is a diagram for describing the manufacturing method of the semiconductor apparatus 10 according to the first embodiment.

FIG. 7 is a diagram showing the state shown in FIG. 6 from the positive direction side of the X-axis.

FIG. 8 is a diagram for describing the manufacturing method of the semiconductor apparatus 10 according to the first embodiment.

FIG. 9 is a diagram showing the state shown in FIG. 8 from the positive direction side of the X-axis.

FIG. 10 is a diagram for describing the manufacturing method of the semiconductor apparatus 10 according to the first embodiment.

FIG. 11 is a diagram showing the state shown in FIG. 10 from the positive direction side of the X-axis.

FIG. 12 is a diagram for describing the manufacturing method of the semiconductor apparatus 10 according to the first embodiment.

FIG. 13 is a diagram showing the state shown in FIG. 12 from the positive direction side of the X-axis.

FIG. 14 is a diagram for describing the manufacturing method of the semiconductor apparatus 10 according to the first embodiment.

FIG. 15 is a diagram showing the state shown in FIG. 14 from the positive direction side of the X-axis.

FIG. 16 is a diagram for describing the manufacturing method of the semiconductor apparatus 10 according to the first embodiment.

FIG. 17 is a diagram showing the state shown in FIG. 16 from the positive direction side of the X-axis.

FIG. 18 is a diagram for describing the manufacturing method of the semiconductor apparatus 10 according to the first embodiment.

FIG. 19 is a diagram showing the state shown in FIG. 18 from the positive direction side of the X-axis.

FIG. 20 is a diagram for describing the manufacturing method of the semiconductor apparatus 10 according to the first embodiment.

FIG. 21 is a diagram showing the state shown in FIG. 20 from the positive direction side of the X-axis.

FIG. 22 is a diagram for describing the manufacturing method of the semiconductor apparatus 10 according to the first embodiment.

FIG. 23 is a diagram showing the state shown in FIG. 22 from the positive direction side of the X-axis.

FIG. 24 is a diagram for describing the manufacturing method of the semiconductor apparatus 10 according to the first embodiment.

FIG. 25 is a diagram showing the state shown in FIG. 24 from the positive direction side of the X-axis.

FIG. 26 is a diagram for describing the manufacturing method of the semiconductor apparatus 10 according to the first embodiment.

FIG. 27 is a diagram showing the state shown in FIG. 26 from the positive direction side of the X-axis.

FIG. 28 is a diagram for describing the manufacturing method of the semiconductor apparatus 10 according to the first embodiment.

FIG. 29 is a diagram showing the state shown in FIG. 28 from the positive direction side of the X-axis.

FIG. 30 is a diagram for describing the manufacturing method of the semiconductor apparatus 10 according to the first embodiment.

FIG. 31 is a diagram showing the state shown in FIG. 30 from the negative direction side of the X-axis.

FIG. 32 is a diagram for describing the manufacturing method of the semiconductor apparatus 10 according to the first embodiment.

FIG. 33 is a diagram showing the state shown in FIG. 32 from the negative direction side of the X-axis.

FIG. 34 is a diagram for describing the manufacturing method of the semiconductor apparatus 10 according to the first embodiment.

FIG. 35 is a diagram showing the state shown in FIG. 34 from the negative direction side of the X-axis.

FIG. 36 is a diagram for describing the manufacturing method of the semiconductor apparatus 10 according to the first embodiment.

FIG. 37 is a diagram showing the state shown in FIG. 36 from the negative direction side of the X-axis.

FIG. 38 is a diagram for describing the manufacturing method of the semiconductor apparatus 10 according to the first embodiment.

FIG. 39 is a diagram showing the state shown in FIG. 38 from the negative direction side of the X-axis.

FIG. 40 is a diagram for describing the manufacturing method of the semiconductor apparatus 10 according to the first embodiment.

FIG. 41 is a diagram showing the state shown in FIG. 40 from the positive direction side of the X-axis.

FIG. 42 is a schematic perspective view of a semiconductor apparatus 50 according to a second embodiment.

FIG. 43 is a schematic perspective view in which the semiconductor apparatus 50 shown in FIG. 42 is disassembled in half along the Y-axis direction.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solving means of the invention.

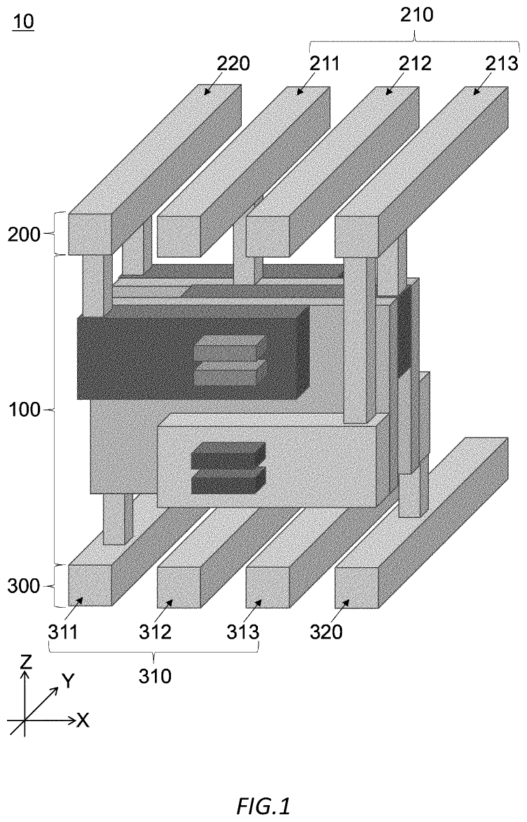

FIG. 1 is a schematic perspective view of a semiconductor apparatus 10 according to a first embodiment. In FIG. 1, an X-axis, a Y-axis, and a Z-axis that are orthogonal to one another are shown with arrows. Also in the subsequent drawings, X, Y, and Z axes corresponding to the X, Y, and Z axes shown in FIG. 1 are shown with arrows. In the following descriptions, the positive side of the Z-axis may be referred to as the upper side, and the negative side of the Z-axis may be referred to as the lower side.

The semiconductor apparatus 10 according to the first embodiment includes a transistor element layer 100, a first wiring layer 200, and a second wiring layer 300. The semiconductor apparatus 10 may include a plurality of a laminate-type CMOS cell as shown in FIG. 1 for example. Note that, in the following descriptions, the cell shown in FIG. 1 may be simply referred to as the semiconductor apparatus 10.

The transistor element layer 100 includes a plurality of transistors that are multi-gate transistors of a floating body structure. The transistors in the transistor element layer 100 are, for example, Field Effect Transistors (FET). The plurality of transistors in the transistor element layer 100 may constitute a two-input NAND circuit.

The floating body structure may refer to a structure that does not require a contact for fixing potential in a channel portion of a transistor. The multi-gate transistor may refer to a structure in which a gate is provided for two or more sides of a three-dimensional channel, and it can include a nanosheet FET, a forksheet FET, a FinFET, a Gate All Around FET (GAA FET), and the like, for example.

The first wiring layer 200 is laminated on the side of one surface of the transistor element layer 100, for example, on the upper side of the transistor element layer 100. The first wiring layer 200 has at least one signal line 210. In the example shown in FIG. 1, the first wiring layer 200 has a signal line 211, a signal line 212, and a signal line 213.

The signal line 210 is a line which electrically connects between a source and a gate or between a drain and a gate of at least one pair of transistors of the plurality of transistors included in the transistor element layer 100.

The first wiring layer 200 may further have at least one power supply line 220. The power supply line 220 is a line which supplies power supply voltage to a circuit achieved by using the plurality of transistors formed in the transistor element layer 100. The power supply line 220 is connected to a source or a drain of at least some transistors among the plurality of transistors included in the transistor element layer 100, and applies power supply current to the connected source or drain.

The second wiring layer 300 is laminated on the side of another surface of the transistor element layer 100, for example, on the lower side of the transistor element layer 100. The second wiring layer 300 has at least one signal line 310. In the example shown in FIG. 1, the second wiring layer 300 has a signal line 311, a signal line 312, and a signal line 313.

The signal line 310 is a line which electrically connects between a source and a gate or between a drain and a gate of at least another pair of transistors excluding the above-described at least one pair of transistors connected by the signal line 210 among the plurality of transistors included in the transistor element layer 100.

The second wiring layer 300 may further have at least one ground line 320. The ground line 320 is a line which grounds a circuit achieved by using the plurality of transistors formed in the transistor element layer 100. One end of the ground line 320 is connected to drains or sources of at least some transistors among the plurality of transistors included in the transistor element layer 100, and another end of the ground line 320 is grounded.

Note that, the signal line 210 and the signal line 310 are also regarded as lines leading from a source or a drain of one transistor to a gate of another transistor, and/or lines leading to a gate of the one transistor. For example, in one pair of transistors in two CMOS cells adjacent in the Y-axis direction, the signal line 210 and the signal line 310 each may electrically connect between a source of one CMOS cell and a gate of another CMOS cell, or may electrically connect between a drain of the one CMOS cell and the gate of the another CMOS cell. Note that, potential of the signal line 210 and the signal line 310 is not fixed, and is varied. Note that, the signal line 210, the signal line 310, the power supply line 220, and the ground line 320 are made of copper, for example.

The semiconductor apparatus 10 according to the present embodiment includes a wiring layer on both surfaces of the transistor element layer 100. Specifically, the first wiring layer 200 is laminated on the side of the one surface of the transistor element layer 100, and the second wiring layer 300 is laminated on the side of the another surface of the transistor element layer 100. In this manner, as compared to a semiconductor apparatus in which only a power supply line or a ground line is formed on the lower side of a transistor element layer and a signal line is formed only on the upper side of the transistor element layer for example, the semiconductor apparatus 10 enhances the density of the signal line 210 and the signal line 310, and enhances degrees of freedom of designs of wirings formed in the first wiring layer 200 and the second wiring layer 300, for example, the signal line 210, the signal line 310, the power supply line 220, the ground line 320, and the like. For example, the semiconductor apparatus 10 allows formation of a contact to be connected to a transistor of the transistor element layer 100 from both the first wiring layer 200 and the second wiring layer 300.

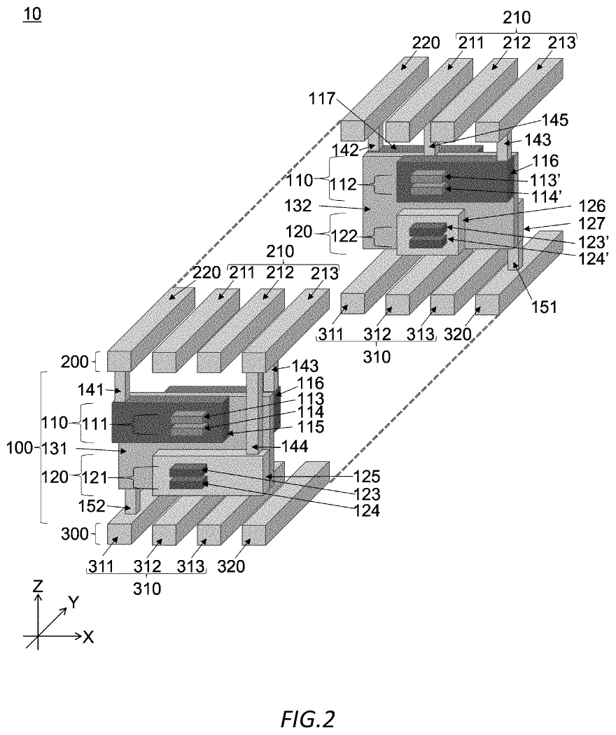

FIG. 2 is a schematic perspective view in which the semiconductor apparatus 10 shown in FIG. 1 is disassembled in half along the Y-axis direction. FIG. 2 shows two linear dashed lines joining the two disassembled portions of the semiconductor apparatus 10.

In the present embodiment, the transistor element layer 100 has a P-type transistor element layer 110, an N-type transistor element layer 120, and one pair of gate electrodes 131, 132 disposed opposite to each other that are common to the P-type transistor element layer 110 and the N-type transistor element layer 120. The transistor element layer 100 further has first contacts 141, 142, 143, 144, 145, and second contacts 151, 152.

The P-type transistor element layer 110 may be positioned on the side of the above-described one surface of the transistor element layer 100, and the N-type transistor element layer 120 may be positioned on the side of the above-described another surface of the transistor element layer 100. Specifically, the P-type transistor element layer 110 may be positioned on the upper side of the transistor element layer 100, and the N-type transistor element layer 120 may be positioned on the lower side of the transistor element layer 100.

The P-type transistor element layer 110 has each P-type transistor of the plurality of transistors included in the transistor element layer 100. The P-type transistor element layer 110 may have a nanosheet structure, and for example, the cell shown in FIG. 2 has P-type transistors 111, 112 of a nanosheet structure.

The P-type transistor 111 includes one or more P-type channels 113, 114, P-type epitaxial layers 115, 116, and the gate electrode 131. The P-type transistor 111 constitutes a multi-gate transistor of a GAA structure with the gate electrode 131 positioned in a surrounding of the one or more P-type channels 113, 114.

The P-type transistor 112 includes one or more P-type channels 113′, 114′, the P-type epitaxial layer 116, a P-type epitaxial layer 117, and the gate electrode 132. The P-type transistor 112 constitutes a multi-gate transistor of a GAA structure with the gate electrode 132 positioned in a surrounding of the one or more P-type channels 113′, 114′. Note that, the P-type channels 113′, 114′ are each formed integrally with the P-type channels 113, 114, respectively, but the P-type channels 113′, 114′ may be described distinctively from the P-type channels 113, 114, or these may be collectively referred to as the P-type channels 113, 114.

Specifically, regarding the P-type channels 113, 114, the P-type epitaxial layer 115 and the P-type epitaxial layer 116 which are doped into P-type are laminated on both sides of the gate electrode 131, and in this manner, both sides of the gate electrode 131 are doped into P-type. In addition, regarding the P-type channels 113, 114, the P-type epitaxial layer 116 and the P-type epitaxial layer 117 which are doped into P-type are laminated on both sides of the gate electrode 132, and in this manner, both sides of the gate electrode 132 are doped into P-type. Furthermore, the P-type channels 113, 114 have a non-doped region at each position of the gate electrode 131 and the gate electrode 132. Note that, the P-type channels 113, 114 are insulated from each of the gate electrode 131 and the gate electrode 132 by an insulating material.

The P-type epitaxial layer 115 and the P-type epitaxial layer 117 are connected to the first contact 141 and the first contact 142 extending from the power supply line 220 of the first wiring layer 200, and are electrically connected to the power supply line 220 via the first contact 141 and the first contact 142. The P-type epitaxial layer 116 is connected to the first contact 143 extending from the signal line 213 of the first wiring layer 200, and is electrically connected to the signal line 213 via the first contact 143.

The N-type transistor element layer 120 is laminated on one side, for example, on the lower side of the P-type transistor element layer 110. The N-type transistor element layer 120 has each N-type transistor of the plurality of transistors included in the transistor element layer 100. The N-type transistor element layer 120 may have a nanosheet structure, and for example, the cell shown in FIG. 2 has N-type transistors 121, 122 of a nanosheet structure.

The N-type transistor 121 includes one or more N-type channels 123, 124, N-type epitaxial layers 125, 126, and the gate electrode 131. The N-type transistor 121 constitutes a multi-gate transistor of a GAA structure with the gate electrode 131 positioned in a surrounding of the one or more N-type channels 123, 124.

The N-type transistor 122 includes one or more N-type channels 123′, 124′, the N-type epitaxial layer 126, an N-type epitaxial layer 127, and the gate electrode 132. The N-type transistor 122 constitutes a multi-gate transistor of a GAA structure with the gate electrode 132 positioned in a surrounding of the one or more N-type channels 123′, 124′. Note that, the N-type channels 123′, 124′ are each formed integrally with the N-type channels 123, 124, respectively, but the N-type channels 123′, 124′ may be described distinctively from the N-type channels 123, 124, or these may be collectively referred to as the N-type channels 123, 124.

Specifically, regarding the N-type channels 123, 124, the N-type epitaxial layer 125 and the N-type epitaxial layer 126 which are doped into N-type are laminated on both sides of the gate electrode 131, and in this manner, both sides of the gate electrode 131 are doped into N-type. In addition, regarding the N-type channels 123, 124, the N-type epitaxial layer 126 and the N-type epitaxial layer 127 which are doped into N-type are laminated on both sides of the gate electrode 132, and in this manner, both sides of the gate electrode 132 are doped into N-type. Furthermore, the N-type channels 123, 124 have a non-doped region at each position of the gate electrode 131 and the gate electrode 132. Note that, the N-type channels 123, 124 are insulated from each of the gate electrode 131 and the gate electrode 132 by an insulating material.

The N-type epitaxial layer 125 is connected to the first contact 144 extending from the signal line 213 of the first wiring layer 200, and is electrically connected to the signal line 213 via the first contact 144. The N-type epitaxial layer 127 is connected to the second contact 151 extending from the ground line 320 of the second wiring layer 300, and is electrically connected to the ground line 320 via the second contact 151.

The gate electrode 131 is connected to the first contact 145 extending from the signal line 211 of the first wiring layer 200, and is electrically connected to the signal line 211 via the first contact 145. The gate electrode 132 is connected to the second contact 152 extending from the signal line 311 of the second wiring layer 300, and is electrically connected to the signal line 311 via the second contact 152.

In this manner, the transistor element layer 100 according to the present embodiment has the nanosheet structure in each of the P-type transistor element layer 110 and the N-type transistor element layer 120. The transistor element layer 100 also has a Complementary FET (CFET) structure in which the P-type transistor 111 and the N-type transistor 121 laminated on a same region in a laminated direction among the plurality of transistors function as a CMOS. The transistor element layer 100 also has a CFET structure in which the P-type transistor 112 and the N-type transistor 122 laminated on a same region in a laminated direction among the plurality of transistors function as a CMOS.

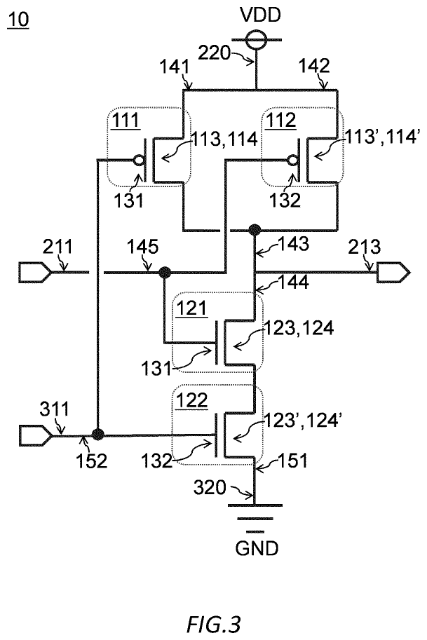

FIG. 3 is an example of a circuit diagram of the semiconductor apparatus 10 according to the first embodiment. As described above, the P-type transistors 111, 112 and the N-type transistors 121, 122 in the transistor element layer 100 of the semiconductor apparatus 10 may constitute the two-input NAND circuit shown in FIG. 3. Numerals shown on the circuit diagram of FIG. 3 correspond to the reference numerals of each configuration of the semiconductor apparatus 10 described in FIG. 1 and FIG. 2, and overlapping descriptions will be omitted.

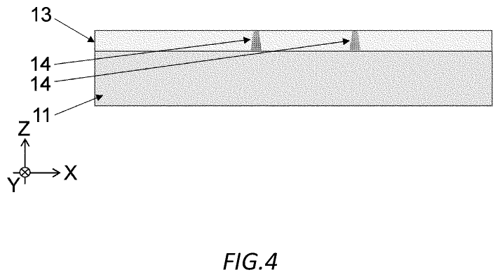

FIG. 4 to FIG. 41 are diagrams for describing a manufacturing method of the semiconductor apparatus 10 according to the first embodiment. Each figure of the even numbers in FIG. 4 to FIG. 41 shows a schematic diagram when each state in a process of manufacturing of the semiconductor apparatus 10 is seen from the negative side of the Y-axis, and it does not show a cross section obtained by virtually cutting each laminated component at a particular X-Z plane. Similarly, each figure of the odd numbers in FIG. 4 to FIG. 41 shows a schematic diagram when each state in the process of manufacturing of the semiconductor apparatus 10 is seen from the positive side of the X-axis, and it does not show a cross section obtained by virtually cutting each laminated component at a particular Y-Z plane. That is, each configuration shown in each figure of FIG. 4 to FIG. 41 is not necessarily positioned within the same X-Z plane or Y-Z plane.

The manufacturing method of the semiconductor apparatus 10 includes forming the transistor element layer 100, laminating the first wiring layer 200 on the side of the one surface of the transistor element layer 100, and laminating the second wiring layer 300 on the side of the another surface of the transistor element layer 100.

As shown in FIG. 4 to FIG. 13, the forming the transistor element layer 100 may include forming a first insulating film 13 on a substrate 11, and forming a non-doped laminated body having a nanosheet structure on the first insulating film 13.

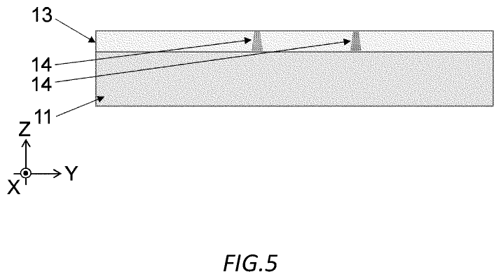

FIG. 4 shows a state in which the first insulating film 13 is formed on the substrate 11. FIG. 5 is a diagram showing the state shown in FIG. 4 from the positive direction side of the X-axis. The first insulating film 13 may be formed of, for example, silicon oxide. The forming the laminated body described above may include forming, on the substrate 11, the first insulating film 13 made of a particular material having a different etching rate from the surrounding region, in a particular region 14 where the second contacts 151, 152 are formed.

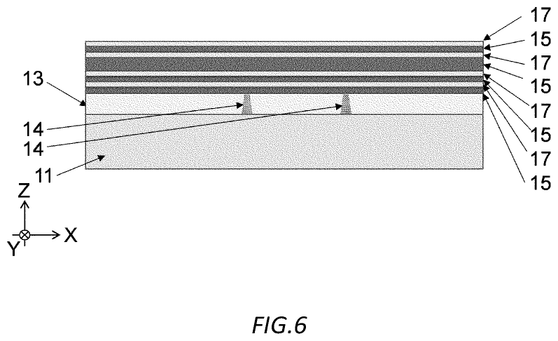

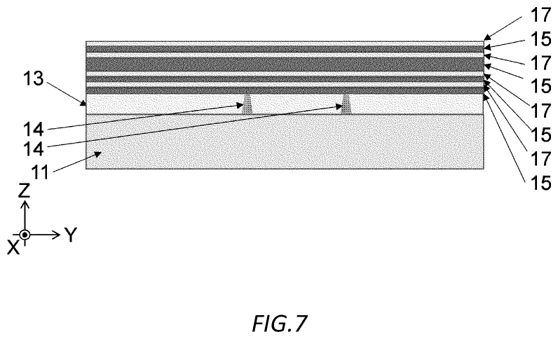

FIG. 6 shows a state in which a silicon-germanium film 15 and a silicon film 17 are laminated alternately and repeatedly on the first insulating film 13 to form the non-doped laminated body having the nanosheet structure. FIG. 7 is a diagram showing the state shown in FIG. 6 from the positive direction side of the X-axis. The silicon film 17 is the predecessor of the nanosheet, and is not doped with either of a P-type ion or an N-type ion. Note that, the number of laminations of the silicon film 17 corresponds to the number of nanosheets in the transistor element layer 100.

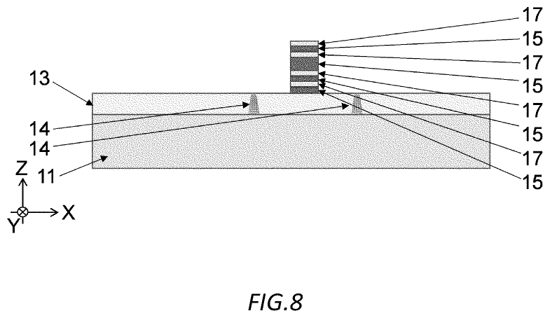

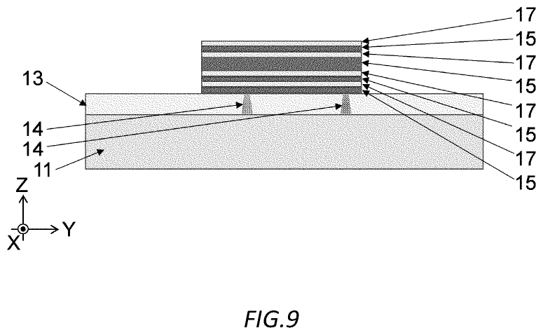

FIG. 8 shows a state in which masking and patterning are performed on a region corresponding to the above-described laminated body. FIG. 9 is a diagram showing the state shown in FIG. 8 from the positive direction side of the X-axis. When performing this patterning, positioning of a pattern of the region corresponding to the laminated body may be performed by using a pattern of the first insulating film 13 as a reference. As a result, the laminated body may be positioned with respect to the particular region 14 where the second contacts 151, 152 are formed in the first insulating film 13.

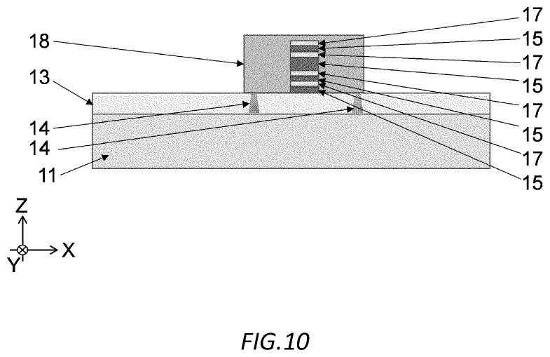

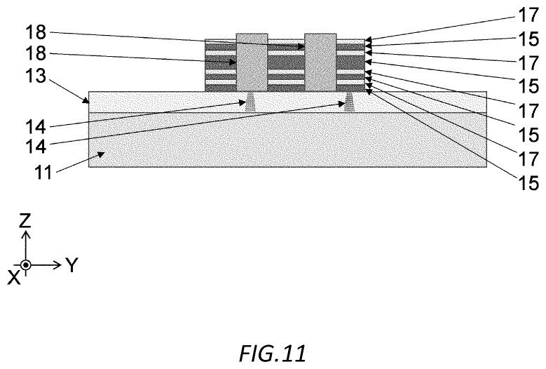

FIG. 10 shows a state in which a temporary gate electrode 18 is formed in a surrounding of the repeating layer of the silicon-germanium film 15 and the silicon film 17. FIG. 11 is a diagram showing the state shown in FIG. 10 from the positive direction side of the X-axis. As shown in FIG. 11, one pair of the temporary gate electrodes 18 are disposed opposite to each other along the Y-axis correspondingly to the gate electrodes 131, 132 disposed opposite to each other of the semiconductor apparatus 10. An end part and a center portion of the repeating layer in the Y-axis direction are not enclosed by the one pair of temporary gate electrodes 18, and are exposed.

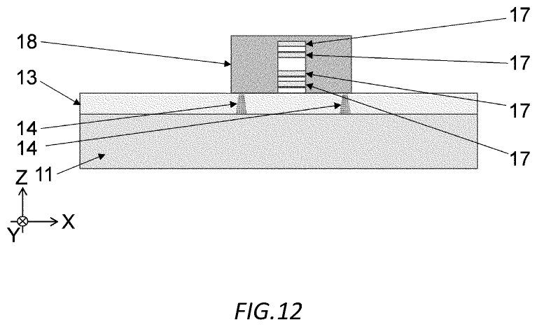

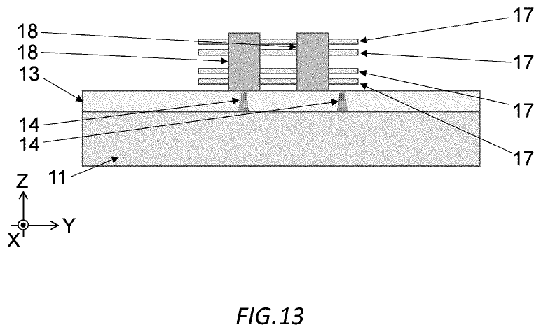

FIG. 12 shows a state in which an etchant is penetrated from a surrounding of the repeating layer shown in FIG. 10 and FIG. 11, and the silicon-germanium film 15 is selectively removed. FIG. 13 is a diagram showing the state shown in FIG. 12 from the positive direction side of the X-axis. As shown in FIG. 12 and FIG. 13, the silicon film 17 that is remained without being removed is retained on the substrate 11 by the temporary gate electrode 18. As shown in FIG. 12 and FIG. 13, four silicon films 17, i.e., four nanosheets are formed correspondingly to the P-type channels 113, 114 and the N-type channels 123, 124 of the semiconductor apparatus 10. In this manner, the non-doped laminated body having the nanosheet structure may be formed on the first insulating film 13.

As have been described in FIG. 4 to FIG. 13 as above, the forming the transistor element layer 100 may include forming the first insulating film 13 on the substrate 11, and forming the above-described laminated body on the first insulating film 13. Alternatively, the forming the transistor element layer 100 may include forming a crystal structure layer having a crystal structure on the substrate 11 and forming the above-described laminated body on the crystal structure layer, and then selectively removing the crystal structure layer and replacing it with an insulating substance, thereby forming the first insulating film 13. The selectively removing the crystal structure layer may include forming an opening for etching in a part of the above-described laminated body, and selectively removing the crystal structure layer through the opening. The crystal structure layer may be formed of, for example, silicon-germanium. The insulating substance forming the first insulating film 13 may be formed of, for example, silicon oxide as described above.

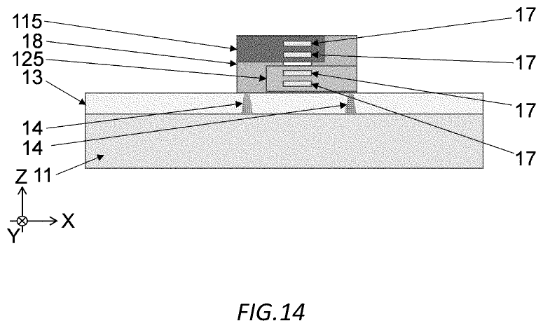

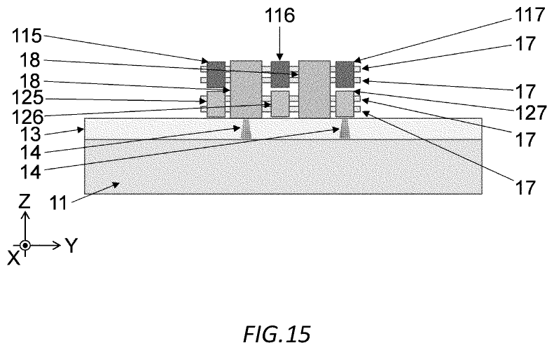

The forming transistor element layer 100 described above may include, as shown in FIG. 14 to FIG. 15, forming an epitaxial layer doped into P-type or N-type in at least both end parts of the above-described laminated body, thereby doping the at least both end parts into P-type or N-type.

FIG. 14 shows a state in which the P-type epitaxial layer 115 is formed in an end part on the negative side of the Y-axis of two nanosheets on the upper side in the laminated body, and the N-type epitaxial layer 125 is formed in the end part on the negative side of the Y-axis of two nanosheets on the lower side in the laminated body.

FIG. 15 is a diagram showing the state shown in FIG. 14 from the positive direction side of the X-axis. As shown in FIG. 15, the P-type epitaxial layer 116 is formed in a center portion that is positioned between the one pair of temporary gate electrodes 18 of the two nanosheets on the upper side in the laminated body. The P-type epitaxial layer 117 is formed in an end part on the positive side of the Y-axis of the two nanosheets on the upper side in the laminated body.

Similarly, the N-type epitaxial layer 126 is formed in a center portion that is positioned between the one pair of temporary gate electrodes 18 of the two nanosheets on the lower side in the laminated body. The N-type epitaxial layer 127 is formed in an end part on the positive side of the Y-axis of the two nanosheets on the lower side in the laminated body.

By performing a heat treatment on the laminated body where the P-type epitaxial layers 115, 116, 117 and the N-type epitaxial layers 125, 126, 127 are formed, a region enclosed by each epitaxial layer in each nanosheet of the laminated body is doped into P-type or N-type. Note that, a region not enclosed by each epitaxial layer, i.e., a region enclosed by the one pair of temporary gate electrodes 18, in each nanosheet of the laminated body remains non-doped.

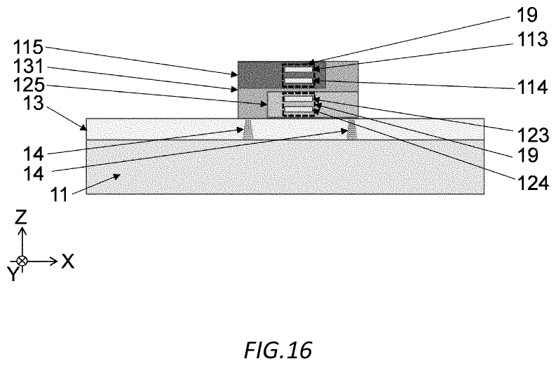

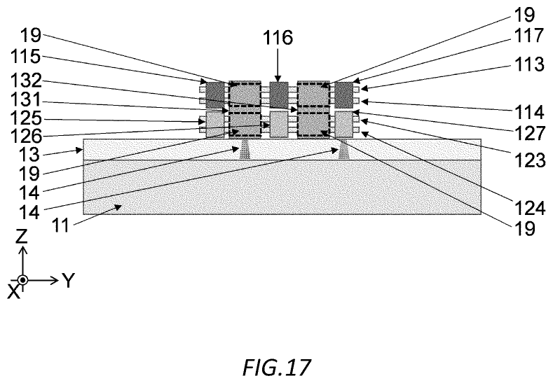

The forming the transistor element layer 100 described above may include surrounding, with a second insulating film 19, entire circumferences of each of a non-doped region excluding at least the both end parts described above doped into P-type in a laminated body for a P-type channel among the laminated body and a non-doped region excluding at least the both end parts described above doped into N-type in a laminated body for an N-type channel among the laminated body, and forming at least one gate electrode enclosing an entire circumference of the second insulating film 19, thereby forming a transistor having the P-type channels 113, 114 and the N-type channels 123, 124. As shown in FIG. 16 to FIG. 17, the forming the transistor may include surrounding, with the second insulating film 19, each of entire circumferences of two different non-doped regions excluding at least the both end parts described above doped into P-type in the laminated body for the P-type channel among the laminated body and two different non-doped regions excluding at least the both end parts described above doped into N-type in the laminated body for the N-type channel among the laminated body, and forming the two gate electrodes 131, 132 enclosing the entire circumference of each second insulating film 19, thereby forming the transistor having the P-type channels 113, 114 and the N-type channels 123, 124. Note that, the transistor having the P-type channels 113, 114 and the N-type channels 123, 124 mentioned herein includes, for example, the P-type transistors 111, 112 and the N-type transistors 121, 122 shown in FIG. 2.

FIG. 16 shows a state in which the temporary gate electrode 18 is replaced with the gate electrode 131. The second insulating film 19 shown with a dashed line in FIG. 16 is formed between each of the gate electrode 131 and the P-type channels 113, 114, and the N-type channels 123, 124. FIG. 17 is a diagram showing the state shown in FIG. 16 from the positive direction side of the X-axis. As shown in FIG. 17, the one pair of temporary gate electrodes 18 are replaced with the one pair of gate electrodes 131, 132. The second insulating film 19 shown with a dashed line in FIG. 17 is formed also between each of the gate electrode 132 and the P-type channels 113, 114, and the N-type channels 123, 124.

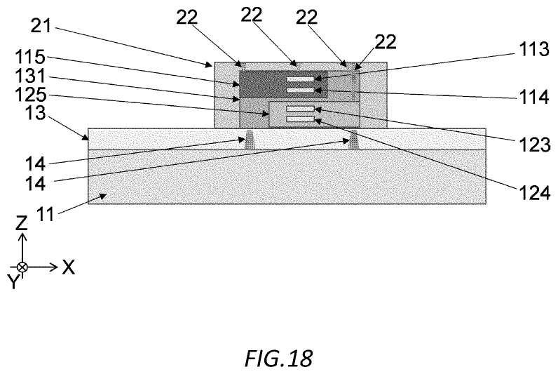

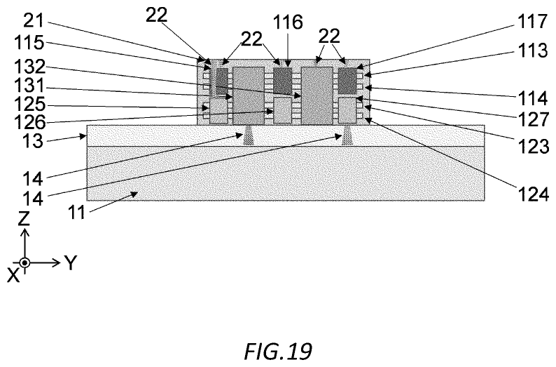

As shown in FIG. 18 to FIG. 19, the forming the transistor element layer 100 described above may include forming an insulating layer 21 entirely protecting the P-type channels 113, 114, the N-type channels 123, 124, and the gate electrodes 131, 132 on the substrate 11.

FIG. 18 shows a state in which the insulating layer 21 which entirely protects the P-type channel 113 and the like on the substrate 11 for insulation is formed. FIG. 19 is a diagram showing the state shown in FIG. 18 from the positive direction side of the X-axis. As shown in FIG. 18 and FIG. 19, the insulating layer 21 made of a particular material having a different etching rate from the surrounding region may be formed in a particular region 22 where the first contacts 141, 142, 143, 144, 145 are formed.

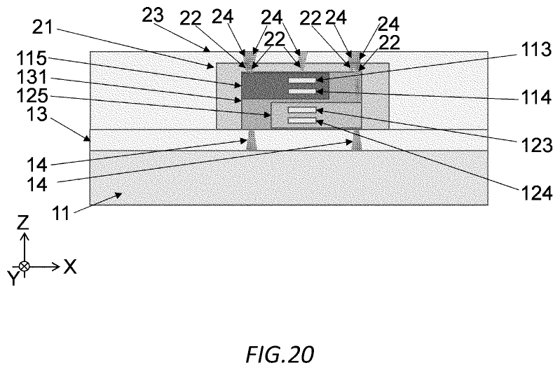

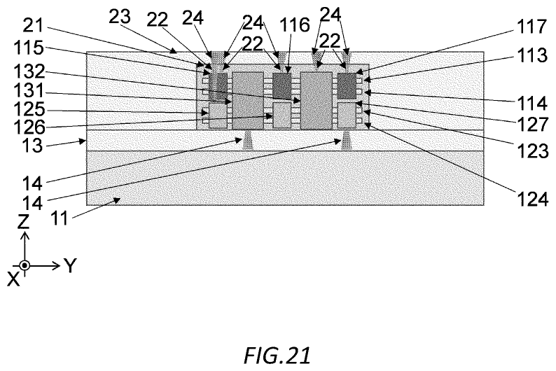

FIG. 20 shows a state in which a third insulating film 23 enclosing the insulating layer 21 on the substrate 11 is formed. FIG. 21 is a diagram showing the state shown in FIG. 20 from the positive direction side of the X-axis. As shown in FIG. 20 and FIG. 21, the third insulating film 23 made of a particular material having a different etching rate from the surrounding region may be formed in a region 24 corresponding to the region 22 in the insulating layer 21.

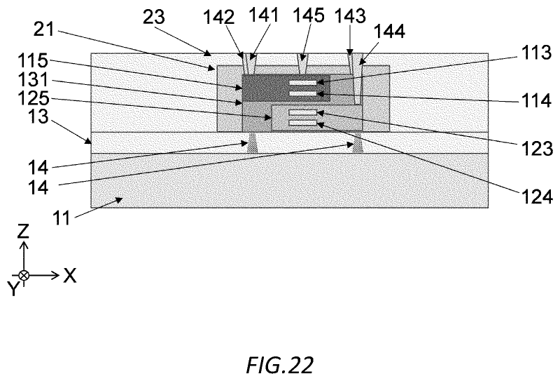

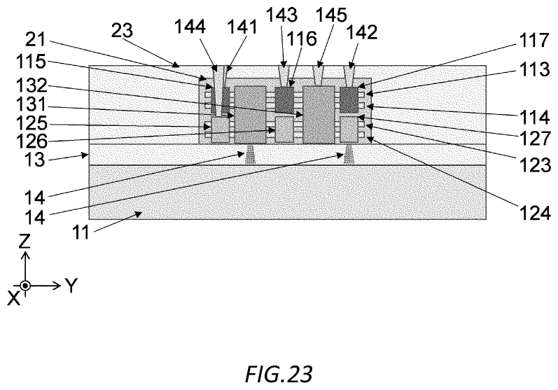

As shown in FIG. 22 to FIG. 23, the forming the transistor element layer 100 described above may include forming at least one first contact to be connected to at least any of the P-type epitaxial layers 115, 116, 117 formed in the P-type channels 113, 114 and the N-type epitaxial layers 125, 126, 127 formed in the N-type channels 123, 124, from the insulating layer 21 side. As shown in FIG. 22 to FIG. 23, the forming the at least one first contact may include forming the first contact to be connected to one of the two gate electrodes 131, 132, from the insulating layer 21 side.

FIG. 22 shows a state in which the first contacts 141, 142 to be connected to the P-type epitaxial layers 115, 117, the first contact 143 to be connected to the P-type epitaxial layer 116, the first contact 144 to be connected to the N-type epitaxial layer 125, and the first contact 145 to be connected to the gate electrode 132 are formed in the region 24 of the third insulating film 23 and the region 22 of the insulating layer 21 shown in FIG. 20 and FIG. 21. FIG. 23 is a diagram showing the state shown in FIG. 22 from the positive direction side of the X-axis. Note that, the region 24 of the third insulating film 23 and the region 22 of the insulating layer 21 shown in FIG. 20 and FIG. 21 are selectively etched to form through holes, and then the first contacts 141 and the like are formed so as to land on the P-type epitaxial layer 115 and the like. Note that, such formation method of the first contact 141 and the like may be referred to as the Self-Aligned Contact (SAC).

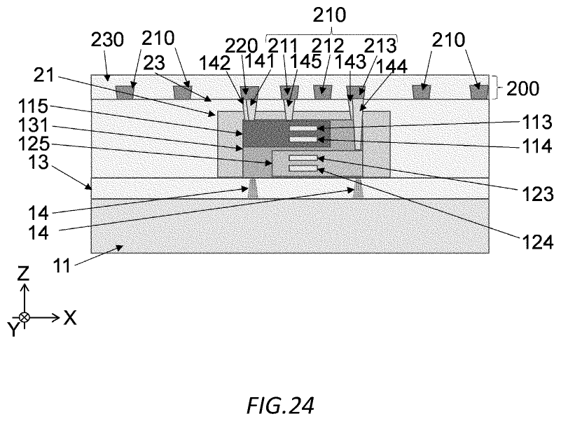

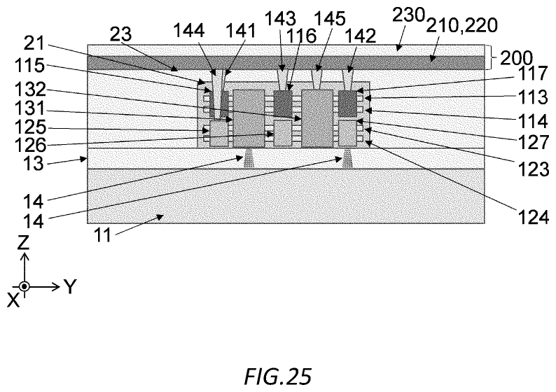

As shown in FIG. 24 to FIG. 25, the laminating the first wiring layer 200 on the side of the one surface of the transistor element layer 100 described above may include forming the first wiring layer 200 including at least one signal line to be connected to at least one first contact on the insulating layer 21.

FIG. 24 shows a state in which the first wiring layer 200 is formed on the insulating layer 21 covered with the third insulating film 23. FIG. 25 is a diagram showing the state shown in FIG. 24 from the positive direction side of the X-axis. As shown in FIG. 24 and FIG. 25, the first wiring layer 200 has a plurality of the signal lines 210 and the power supply line 220, and a fourth insulating film 230 which is formed so as to protect these wirings in a manner that allows insulation of these wirings from each other. As shown in FIG. 24, the signal line 211 is formed on an exposed end part of the first contact 145, the signal line 213 is formed on an exposed end part of the first contacts 143, 144, and the power supply line 220 is formed on an exposed end part of the first contacts 141, 142.

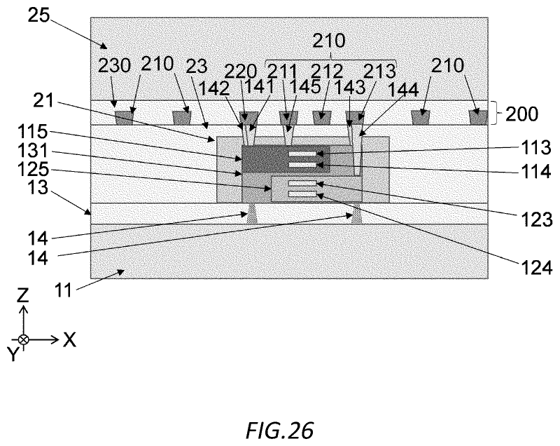

As shown in FIG. 26 to FIG. 31, the forming the transistor element layer 100 described above may include exposing the first insulating film 13 formed on the substrate 11 by removing the substrate 11 in a state where the first wiring layer 200 side is retained by a support substrate 25.

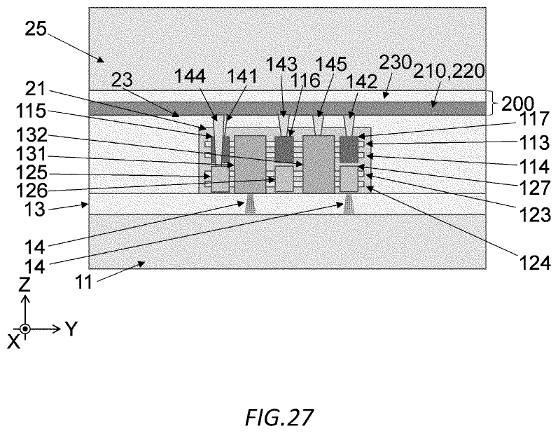

FIG. 26 shows a state in which the support substrate 25 is stuck to the first wiring layer 200 side. FIG. 27 is a diagram showing the state shown in FIG. 26 from the positive direction side of the X-axis. The support substrate 25 may be adhered on the first wiring layer 200 side.

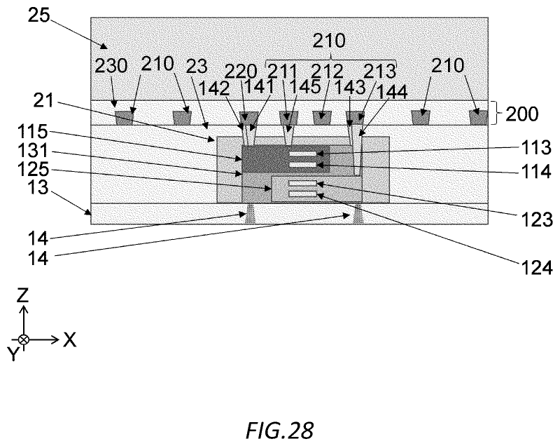

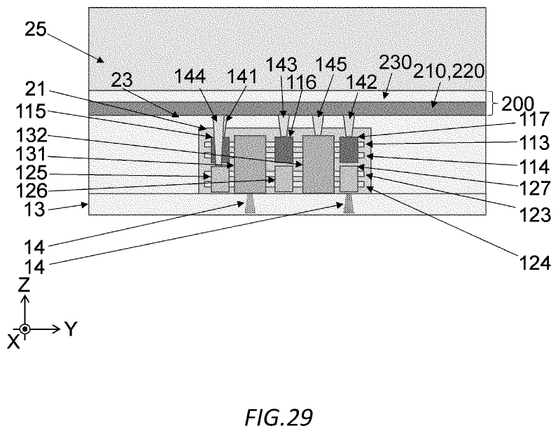

FIG. 28 shows a state in which the substrate 11 is removed in a state where the first wiring layer 200 side is retained by the support substrate 25. FIG. 29 is a diagram showing the state shown in FIG. 28 from the positive direction side of the X-axis. The substrate 11 may be removed by, for example, mechanical polishing. With the removal of the substrate 11, the channels of the transistor of the transistor element layer 100 becomes a floating state where there is no contact from the substrate 11.

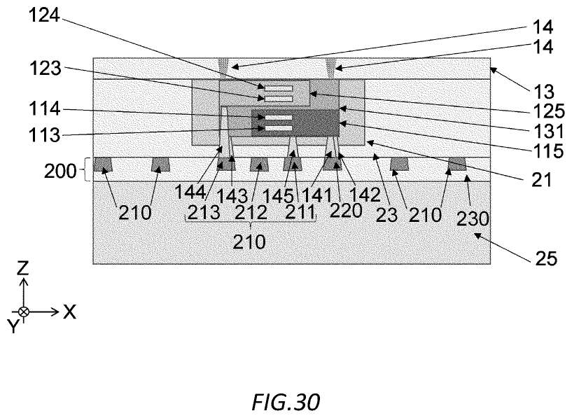

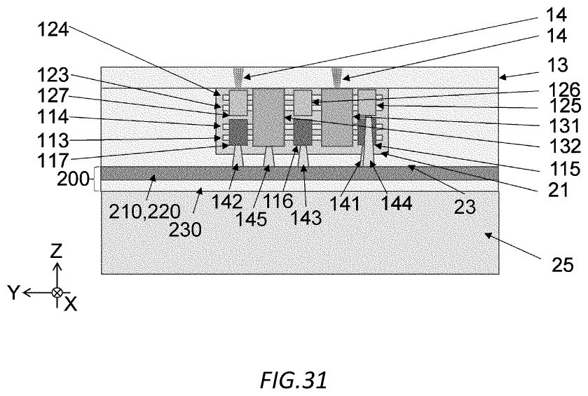

FIG. 30 shows a state in which the first insulating film 13 is positioned on the upper side by rotating the state shown in FIG. 28 and FIG. 29 by 180 degrees around the Y-axis. FIG. 31 is a diagram showing the state shown in FIG. 30 from the negative direction side of the X-axis.

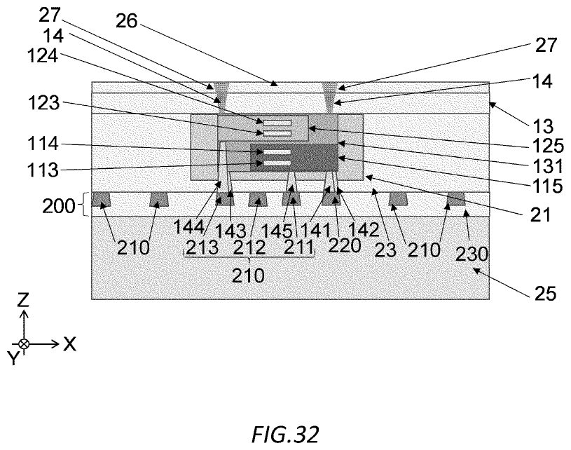

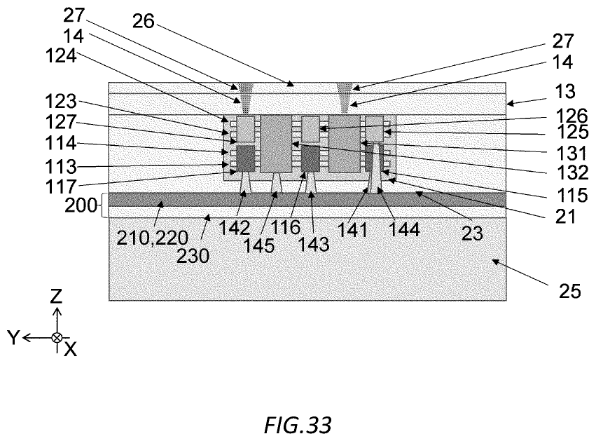

FIG. 32 shows a state in which a fifth insulating film 26 is formed on the first insulating film 13. FIG. 33 is a diagram showing the state shown in FIG. 32 from the negative direction side of the X-axis. As shown in FIG. 32 and FIG. 33, the fifth insulating film 26 made of a particular material having a different etching rate from the surrounding region may be formed in a region 27 corresponding to the region 14 in the first insulating film 13.

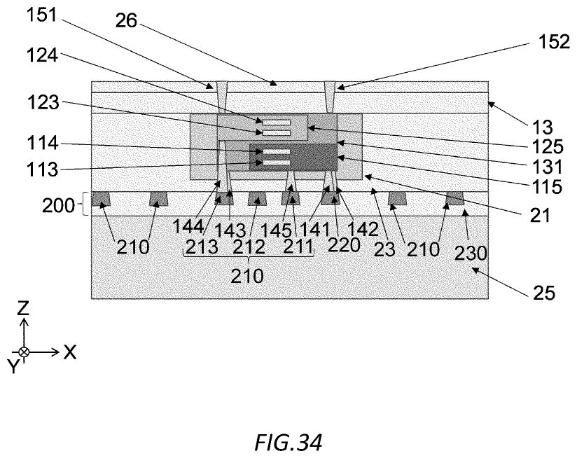

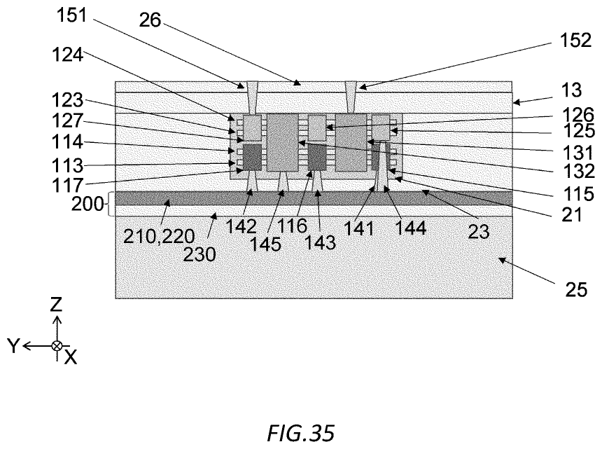

As shown in FIG. 34 to FIG. 35, the forming the transistor element layer 100 described above may include forming at least one second contact to be connected to at least any of the P-type epitaxial layers 115, 116, 117 formed in the P-type channels 113, 114 and the N-type epitaxial layers 125, 126, 127 formed in the N-type channels 123, 124, from the exposed first insulating film 13 side. As shown in FIG. 34 to FIG. 35, the forming the at least one second contact may include forming the second contact to be connected to the one not connected to the first contact of the two gate electrodes 131, 132, from the exposed first insulating film 13 side.

FIG. 34 shows a state in which the second contact 152 connected to the gate electrode 131 is formed in the region 14 of the first insulating film 13 and the region 27 of the fifth insulating film 26 shown in FIG. 32 and FIG. 33. FIG. 35 is a diagram showing the state shown in FIG. 34 from the negative direction side of the X-axis, and it shows a state in which the second contact 151 connected to the N-type epitaxial layer 127 is formed in the region 14 of the first insulating film 13 and the region 27 of the fifth insulating film 26 shown in FIG. 32 and FIG. 33.

The forming the at least one second contact described above may include forming a through hole by selectively etching the particular region 14 among the exposed first insulating film 13, and forming the at least one second contact in the through hole. After the region 14 of the first insulating film 13 and the region 27 of the fifth insulating film 26 shown in FIG. 32 and FIG. 33 are selectively etched to form through holes, the second contact 151 is formed so as to land on the N-type epitaxial layer 127 and the gate electrode 131 is formed so as to land on the second contact 152.

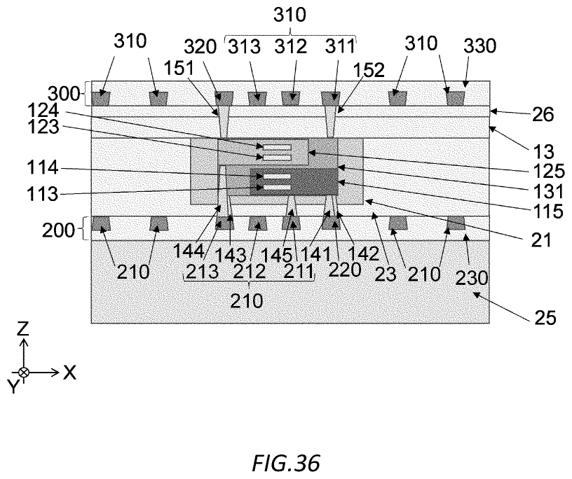

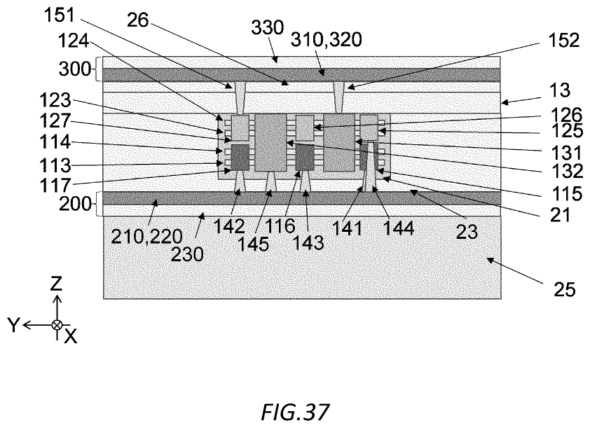

As shown in FIG. 36 to FIG. 37, the laminating the second wiring layer 300 on the side of the another surface of the transistor element layer 100 described above may include forming the second wiring layer 300 including at least one signal line to be connected to at least one second contact on the exposed first insulating film 13.

FIG. 36 shows a state in which the second wiring layer 300 is formed on the first insulating film 13 covered with the fifth insulating film 26. FIG. 36 is a diagram showing the state shown in FIG. 36 from the negative direction side of the X-axis. As shown in FIG. 36 and FIG. 37, the second wiring layer 300 has a plurality of the signal lines 310 and the ground line 320, and a sixth insulating film 330 which is formed so as to protect these wirings in a manner that allows insulation of these wirings from each other. As shown in FIG. 36, the signal line 311 is formed on an exposed end part of the second contact 152, and the ground line 320 is formed on an exposed end part of the second contact 151.

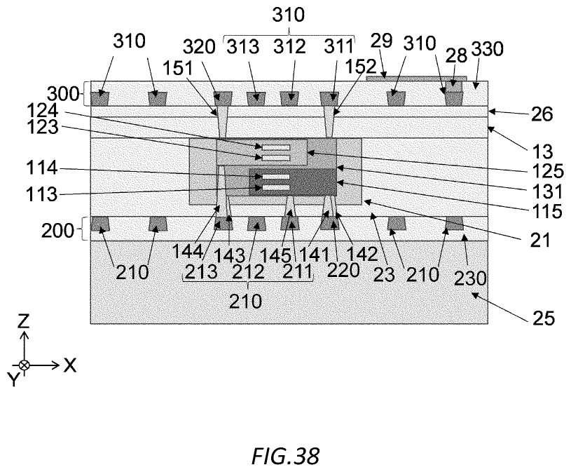

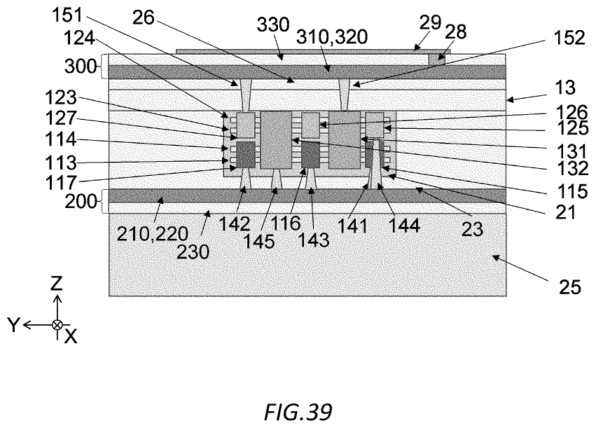

FIG. 38 shows a state in which a via 28 landing on any of the signal lines 310 of the second wiring layer 300, and an electrode pad 29 positioned on an exposed end part of the via 28, are formed. FIG. 39 is a diagram showing the state shown in FIG. 38 from the negative direction side of the X-axis.

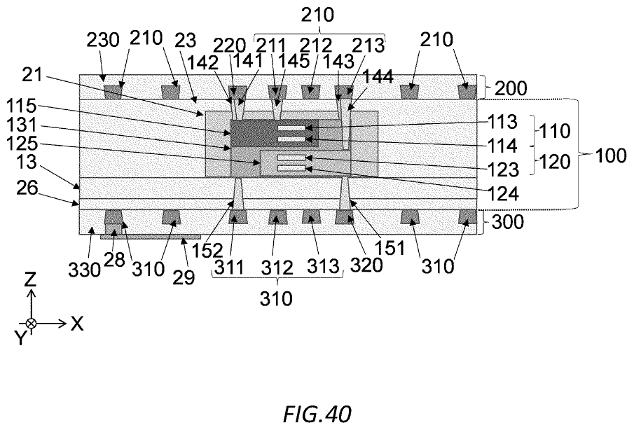

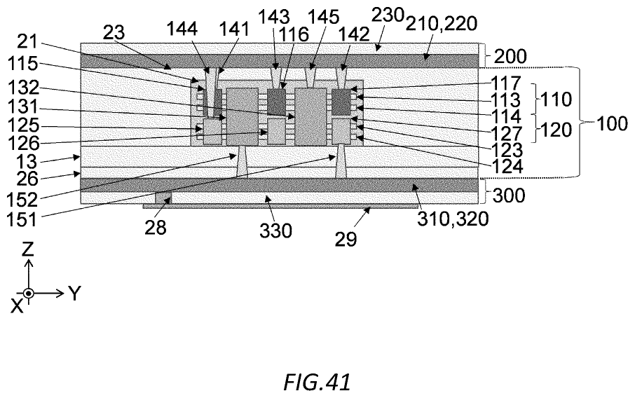

FIG. 40 shows a state in which the state shown in FIG. 38 and FIG. 39 is rotated by 180 degrees around the Y-axis. FIG. 41 is a diagram showing the state shown in FIG. 40 from the positive direction side of the X-axis. In FIG. 40 and FIG. 41, an illustration of the support substrate 25 on the first wiring layer 200 side is omitted. As shown in FIG. 40 and FIG. 41, the semiconductor apparatus 10 including the transistor element layer 100 having the P-type transistor element layer 110 and the N-type transistor element layer 120, the first wiring layer 200, and the second wiring layer 300 may be manufactured by the example of the manufacturing method described in FIG. 4 to FIG. 41 as above.

Note that, in the example of the manufacturing method described in FIG. 4 to FIG. 41 as above, it is described that the insulating layer 21 or the like and the first insulating film 13 or the like made of a particular material having a different etching rate from the surrounding region are formed to form the first contact 141 or the like and the second contact 151 or the like. Instead of or in addition to this, the first contact 141 or the like and the second contact 151 or the like may be formed by forming an etch stop layer in the insulating layer 21 or the like and the first insulating film 13 or the like, and performing etching up to the etch stop layer.

As have been described above, the semiconductor apparatus 10 according to the present embodiment includes wiring layers on both surfaces of the transistor element layer 100. Specifically, the first wiring layer 200 is laminated on the side of the one surface of the transistor element layer 100, and the second wiring layer 300 is laminated on the side of the another surface of the transistor element layer 100. In this manner, as compared to a comparative example which is the semiconductor apparatus in which only a power supply line or a ground line is formed on the lower side of a transistor element layer and a signal line is formed only on the upper side of the transistor element layer for example, the semiconductor apparatus 10 can enhance the density of the signal line 210 and the signal line 310, and can enhance degrees of freedom of designs of wirings formed in the first wiring layer 200 and the second wiring layer 300, for example, the signal line 210, the signal line 310, the power supply line 220, the ground line 320, and the like.

For example, the semiconductor apparatus 10 allows formation of a contact to be connected to a transistor of the transistor element layer 100 from both the first wiring layer 200 and the second wiring layer 300. For example, the semiconductor apparatus 10 allows formation of a contact to be connected to a transistor of the transistor element layer 100 symmetrically from the first wiring layer 200 and the second wiring layer 300. For example, the semiconductor apparatus 10 enables connections to the P-type transistors 111, 112 and the N-type transistors 121, 122 from a surface which is effective in terms of contact resistance. Note that, in the semiconductor apparatus 10, the same power supply input/output as the comparative example of the semiconductor apparatus described above is enabled.

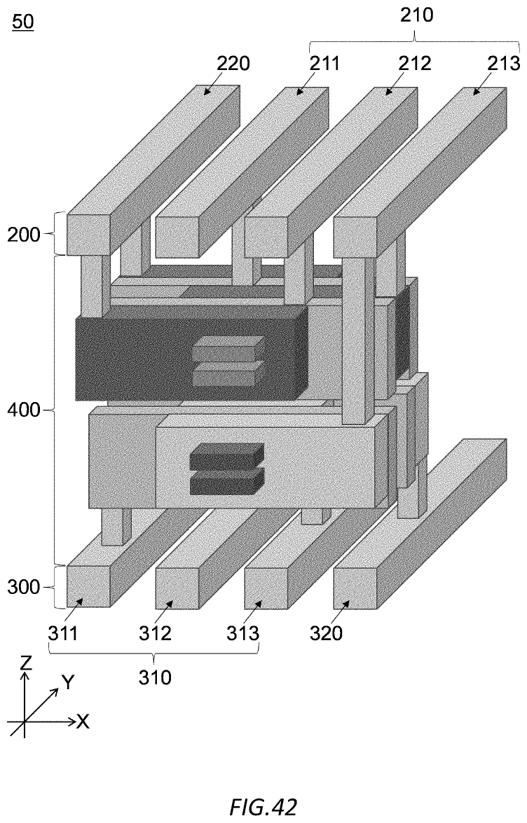

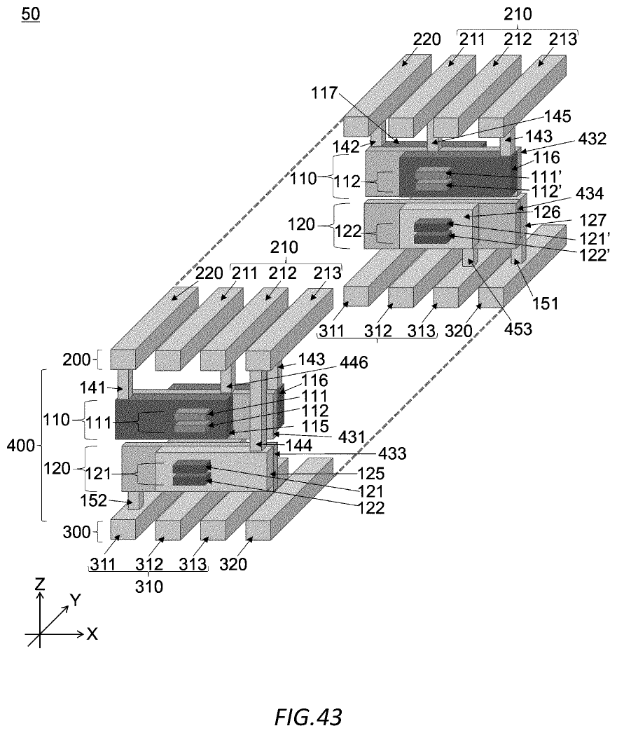

FIG. 42 is a schematic perspective view of a semiconductor apparatus 50 according to a second embodiment. FIG. 43 is a schematic perspective view in which the semiconductor apparatus 50 shown in FIG. 42 is disassembled in half along the Y-axis direction.

The semiconductor apparatus 50 according to the second embodiment differs from the semiconductor apparatus 10 according to the first embodiment in that a transistor element layer 400 has two pairs of gate electrodes 431, 432 and gate electrodes 433, 434, instead of the one pair of gate electrodes 131, 132. In accordance with this, the transistor element layer 400 further additionally has a first contact 446 and a second contact 453. Other configurations in the semiconductor apparatus 50 according to the second embodiment are the same as the semiconductor apparatus 10 according to the first embodiment, and the same reference numeral as each configuration of the semiconductor apparatus 10 according to the first embodiment is used to omit overlapping descriptions.

The transistor element layer 400 of the semiconductor apparatus 50 according to the second embodiment has the one pair of gate electrodes 431, 432 which are disposed opposite to each other in the P-type transistor element layer 110, and the another pair of gate electrodes 433, 434 which are disposed opposite to each other in the N-type transistor element layer 120. The one pair of gate electrodes 431, 432 are connected to the first contacts 145, 446 extending from the signal lines 211, 212 of the first wiring layer 200. The another pair of gate electrodes 433, 434 are connected to the second contacts 152, 453 extending from the signal lines 311, 313 of the second wiring layer 300.

The semiconductor apparatus 50 according to the second embodiment including such configurations exerts the same effect as the semiconductor apparatus 10 according to the first embodiment. Moreover, the semiconductor apparatus 50 according to the second embodiment can shorten contact distances by connecting the first contacts 145, 446 from above for the gate electrodes 431, 432 on the upper side, while connecting the second contacts 152, 453 from underneath for the gate electrodes 433, 434 on the lower side, and can reduce performance degradation due to an influence of parasitic resistance.

In the plurality of embodiments as above, the power supply line 220 is formed in the first wiring layer 200 laminated on the upper side of the transistor element layers 100, 400, and the ground line 320 is formed in the second wiring layer 300 laminated on the lower side of the transistor element layers 100, 400. However, the power supply line 220 may be formed in the second wiring layer 300, and the ground line 320 may be formed in the first wiring layer 200, or both the power supply line 220 and the ground line 320 may be formed in the first wiring layer 200 or the second wiring layer 300.

In the plurality of embodiments as above, the transistor element layers 100, 400 are described as having the nanosheet structure. Instead of or in addition to this, the transistor element layers 100, 400 may have a FinFET structure. Specifically, a transistor of the transistor element layers 100, 400 may have a structure in which at least either of the P-type channels 113, 114 or the N-type channels 123, 124 are formed in a longitudinal direction with respect to a laminated surface of the transistor element layers 100, 400.

While the present invention has been described with the embodiments, the technical scope of the present invention is not limited to the above-described embodiments. It is apparent to persons skilled in the art that various alterations and improvements can be added to the above-described embodiments. It is also apparent from the description of the claims that the embodiments to which such alterations or improvements are made can be included in the technical scope of the present invention.

The operations, procedures, steps, and stages of each process performed by an apparatus, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

### EXPLANATION OF REFERENCES

10: semiconductor apparatus;
100: transistor element layer;
110: P-type transistor element layer;
111, 112: P-type transistor;
113, 113′, 114, 114′: P-type channel;
115, 116, 117: P-type epitaxial layer;
120: N-type transistor element layer;
121, 122: N-type transistor;
123, 123′, 124, 124′: N-type channel;
125, 126, 127: N-type epitaxial layer;
131, 132: gate electrode;
141, 142, 143, 144, 145: first contact;
151, 152: second contact;
200: first wiring layer;
210, 211, 212, 213: signal line;
220: power supply line;
300: second wiring layer;
310, 311, 312, 313: signal line;
320: ground line;
11: substrate;
13: first insulating film;
14: region;
15: silicon-germanium film;
17: silicon film;
18: temporary gate electrode;
19: second insulating film;
21: insulating layer;
22: region;
23: third insulating film;
24: region;
230: fourth insulating film;
25: support substrate;
26: fifth insulating film;
27: region;
330: sixth insulating film;
28: via;
29: electrode pad;
50: semiconductor apparatus;
400: transistor element layer;
431, 432, 433, 434: gate electrode;
446: first contact;
453: second contact.

What is claimed is:

1. A semiconductor apparatus, comprising:
a transistor element layer having a plurality of transistors which are multi-gate transistors of a floating body structure;
a first wiring layer having at least one signal line which electrically connects between a source and a gate or between a drain and a gate of at least one pair of transistors among the plurality of transistors, the first wiring layer being laminated on a side of one surface of the transistor element layer; and
a second wiring layer having at least one signal line which electrically connects between a source and a gate or between a drain and a gate of at least another pair of transistors among the plurality of transistors, the second wiring layer being laminated on a side of another surface of the transistor element layer.

2. The semiconductor apparatus according to claim 1, wherein the transistor element layer has
a P-type transistor element layer having each P-type transistor among the plurality of transistors, and
an N-type transistor element layer having each N-type transistor among the plurality of transistors, the N-type transistor element layer being laminated on one side of the P-type transistor element layer.

3. The semiconductor apparatus according to claim 2, wherein the transistor element layer has a Complementary FET (CFET) structure in which a P-type transistor and an N-type transistor laminated on a same region in a laminated direction among the plurality of transistors function as a CMOS.

4. The semiconductor apparatus according to claim 2, wherein
the first wiring layer has at least one power supply line,
the second wiring layer has at least one ground line,
the P-type transistor element layer is positioned on the side of the one surface of the transistor element layer, and
the N-type transistor element layer is positioned on the side of the another surface of the transistor element layer.

5. The semiconductor apparatus according to claim 2, wherein
the transistor element layer has one pair of gate electrodes disposed opposite to each other, which are common to the P-type transistor element layer and the N-type transistor element layer,
one gate electrode of the one pair of gate electrodes is connected to a first contact extending from a signal line of the first wiring layer, and
another gate electrode of the one pair of gate electrodes is connected to a second contact extending from a signal line of the second wiring layer.

6. The semiconductor apparatus according to claim 2, wherein
the transistor element layer has one pair of gate electrodes disposed opposite to each other in the P-type transistor element layer, and another pair of gate electrodes disposed opposite to each other in the N-type transistor element layer,
the one pair of gate electrodes are connected to a first contact extending from a signal line of the first wiring layer, and
the another pair of gate electrodes are connected to a second contact extending from a signal line of the second wiring layer.

7. The semiconductor apparatus according to claim 1, wherein
the transistor element layer has a nanosheet structure.

8. The semiconductor apparatus according to claim 1, wherein
the transistor element layer has a FinFET structure.

9. A manufacturing method of a semiconductor apparatus, comprising:
forming a transistor element layer having a plurality of transistors which are multi-gate transistors of a floating body structure;
laminating, on a side of one surface of the transistor element layer, a first wiring layer having at least one signal line which electrically connects between a source and a gate or between a drain and a gate of at least one pair of transistors among the plurality of transistors; and
laminating, on a side of another surface of the transistor element layer, a second wiring layer having at least one signal line which electrically connects between a source and a gate or between a drain and a gate of at least another pair of transistors among the plurality of transistors.

10. The manufacturing method according to claim 9, wherein the forming the transistor element layer comprises:
forming a first insulating film on a substrate, and forming a non-doped laminated body having a nanosheet structure or FinFET structure on the first insulating film, or forming a crystal structure layer having a crystal structure on the substrate and forming the laminated body on the crystal structure layer and then selectively remove the crystal structure layer for replacement with an insulating substance, thereby forming the first insulating film;
forming an epitaxial layer doped into P-type or N-type in at least both end parts of the laminated body, thereby doping the at least both end parts into P-type or N-type;
surrounding, with a second insulating film, entire circumferences of each of a non-doped region excluding the at least both end parts doped into P-type in a laminated body for a P-type channel among the laminated body and a non-doped region excluding the at least both end parts doped into N-type in a laminated body for an N-type channel among the laminated body, and forming at least one gate electrode enclosing an entire circumference of the second insulating film, thereby forming a transistor having a P-type channel and an N-type channel; and
forming an insulating layer which entirely protects the P-type channel, the N-type channel, and the at least one gate electrode on the substrate.

11. The manufacturing method according to claim 10, wherein
the forming the transistor element layer comprises forming, from the insulating layer side, at least one first contact to be connected to at least either of the epitaxial layer formed in the P-type channel or the epitaxial layer formed in the N-type channel, and
the laminating the first wiring layer on the side of the one surface of the transistor element layer comprises forming, on the insulating layer, the first wiring layer comprising at least one signal line to be connected to the at least one first contact.

12. The manufacturing method according to claim 11, wherein
the forming the transistor element layer comprises:
in a state where the first wiring layer side is retained by a support substrate, removing the substrate to expose the first insulating film formed on the substrate; and
forming, from the exposed first insulating film side, at least one second contact to be connected to at least either of the epitaxial layer formed in the P-type channel or the epitaxial layer formed in the N-type channel, and
the laminating the second wiring layer on the side of the another surface of the transistor element layer comprises forming, on the exposed first insulating film, a second wiring layer comprising at least one signal line to be connected to the at least one second contact.

13. The manufacturing method according to claim 12, wherein
the forming the laminated body comprises forming, on the substrate, the first insulating film made of a particular material having a different etching rate from a surrounding region in a particular region where the at least one second contact is formed, and
the forming the at least one second contact comprises forming a through hole by selectively etching the particular region among the exposed first insulating film, and forming the at least one second contact in the through hole.

14. The manufacturing method according to claim 12, wherein
the forming the transistor comprises surrounding, with the second insulating film, each of entire circumferences of two different non-doped regions excluding the at least both end parts doped into P-type in the laminated body for the P-type channel among the laminated body and two different non-doped regions excluding the at least both end parts doped into N-type in the laminated body for the N-type channel among the laminated body, and forming two of the gate electrodes enclosing an entire circumference of each second insulating film, thereby forming the transistor having the P-type channel and the N-type channel,
the forming the at least one first contact comprises forming, from the insulating layer side, a first contact to be connected to one of the two gate electrodes, and
the forming the at least one second contact comprises forming, from the exposed first insulating film side, a second contact to be connected to another of the two gate electrodes.
